(19) United States
(12) Patent Application Publication
(10) Pub. No.: US 2023/0012179 A1
(43) Pub. Date: Jan. 12, 2023

(54) METHOD AND VOLTAGE CONVERTER ASSEMBLY FOR SUPPLYING ENERGY TO AT LEAST ONE ELECTRICAL VEHICLE MODULE

(71) Applicant: Robert Bosch GmbH, Stuttgart (DE)

(72) Inventors: Eugen Wang, Illingen (DE); Ruediger Karner, Kornwestheim (DE)

(21) Appl. No.: 17/908,047

(22) PCT Filed: Apr. 12, 2021
(86) PCT No.: PCT/EP2021/059396

§ 371 Date: Aug. 30, 2022

(30) Foreign Application Priority Data
Jun. 4, 2020 (DE) 10 2020 206 997.2

(51) Int. Cl. G01R 19/165; H02J 7/00

(52) U.S. Cl. CPC G01R 19/16576; H02J 7/0047; H02J 7/007182; H02J 2207/20; B60R 16/03

(57) ABSTRACT

A method and a voltage converter assembly for supplying energy to at least one electrical vehicle module. The assembly includes at least one voltage converter that is designed to convert an input voltage, provided by at least one supply source, into at least one predefinable output voltage, which is applied to the at least one vehicle module, a voltage monitor that is designed to detect the input voltage, and an evaluation and control unit that is designed to carry out the method for supplying energy to at least one electrical vehicle module. The supply source is loaded with a predefinable current level when the input voltage that is present exceeds a predefinable setpoint voltage value, the input voltage being converted into at least one output voltage if the input voltage remains above the predefinable setpoint voltage value despite the load on the supply source.

### FIELD

The present invention is directed to a method for supplying energy to at least one electrical vehicle module. Moreover, the subject matter of the present invention relates to a corresponding voltage converter assembly for supplying energy to at least one electrical vehicle module, including an evaluation and control unit that is designed to carry out such a method for supplying energy to at least one electrical vehicle module.

### BACKGROUND INFORMATION

Practically all electronic modules of a vehicle include a circuit portion that converts an externally provided supply voltage to other voltage potentials that are required within the module. Such a circuit portion is also referred to as a voltage converter, and within the specified input voltage delivers one or more defined output voltages for supplying the subsequent modules. To ensure reliable functioning of the voltage converter, a minimum input voltage value is necessary, above which the voltage converter is able to deliver the required output voltage. In common practice, this minimum input voltage value is set only at a certain first voltage value, which when exceeded causes the voltage converter to start with the voltage conversion, and if the voltage drops below a certain second voltage value that matches the first voltage value, the voltage conversion is deactivated. This method is problematic when the input voltage is very close to the activation limit and has a high internal resistance, as the result of which the voltage collapses under load and the voltage converter is deactivated. Due to the resulting sporadic switching on and off of the output voltage, subsequent modules, in particular microcontrollers and microprocessors, may have problematic, unpredictable behavior. The problem of undesirable sporadic switching on and off of the voltage conversion cannot be prevented by a simple hysteresis of the switch-on and switch-off threshold.

A device that includes a plurality of sensors for a vehicle and a generic method for supplying energy to at least one vehicle module are described in German Patent Application No. DE 10 2007 001 573 A1. The device includes an interface via which the device communicates with control units of the vehicle. The device also includes a generic voltage converter assembly that is connectable to the energy network of the vehicle and to the at least one control unit for supplying energy to the at least one control unit, and includes means for the voltage conversion (i.e., a voltage converter). The means for the voltage conversion convert an input voltage from the energy network into at least one output voltage for supplying energy to the at least one control unit. The method checks whether the input voltage from the energy network is present. If this is the case, the conversion of the input voltage into the at least one output voltage continues. However, if this is not the case, an energy reserve is used in order to supply the plurality of sensors and the at least one control unit with energy for a certain autonomy time.

### SUMMARY

A method for supplying energy to at least one electrical vehicle module and a voltage converter assembly for supplying energy to at least one electrical vehicle module, according to example 2 Substitute Specification embodiment of the present invention, have an advantage that the load capacity of a supply source that provides the input voltage for the voltage conversion is checked before the voltage conversion of the input voltage into at least one output voltage is carried out.

The present invention is based on the fact that prior to activating the at least one voltage converter, an internal resistance of the supply source is assessed, and only when this internal resistance drops below a certain value is the at least one voltage converter activated. By use of this method, it may be ensured that upon activation of the at least one voltage converter, the input voltage does not collapse due to the load, thus resulting in deactivation of the voltage converters. That is, when the voltage converters are activated, sufficient input power is also present which ensures continued operation of the voltage converters. Thus, the sporadic switching on and off, which is critical for subsequent stages, can no longer occur.

Specific example embodiments of the present invention provide a method for supplying energy to at least one electrical vehicle module, in which an input voltage that is provided by at least one supply source is monitored and converted into at least one output voltage, which is applied to the at least one vehicle module. The supply source is loaded with a predefinable current level when the input voltage that is present exceeds a predefinable setpoint voltage value, the input voltage being changed or converted into the at least one output voltage if the input voltage remains above the predefinable setpoint voltage value despite load on the supply source.

Also provided is a voltage converter assembly for supplying energy to at least one electrical vehicle module, including at least one voltage converter that is designed to change or convert an input voltage, provided by at least one supply source, into at least one predefinable output voltage that is applied to the at least one vehicle module, a voltage monitor that is designed to detect the input voltage, and an evaluation and control unit that is designed to carry out the method for supplying energy to at least one electrical vehicle module.

Due to the predefined current level, it is possible to easily and quickly check whether the internal resistance of the supply source has a sufficiently small value, so that the supply source may provide the necessary power for operating the at least one voltage converter. The current level for load checking may advantageously be adapted to the specifications of the utilized supply sources and voltage converters.

In the present context, the evaluation and control unit may be understood to mean an electrical module that processes or evaluates detected sensor signals. For this purpose, the evaluation and control unit may include at least one processing unit for processing signals or data, at least one memory unit for storing signals or data, at least one interface to a sensor or another module for reading in sensor signals or for outputting control signals, and/or at least one communication interface for reading in or outputting data that are embedded in a communication protocol. The at least one interface may have a hardware and/or software design. In a hardware design, the interfaces may be part of a so-called system application-specific integrated circuit (ASIC), for example, that includes various functions of the evaluation and control unit. In addition, the evaluation and the control unit itself may be designed as a system application-specific integrated circuit

(ASIC). However, it is also possible for the interfaces to be dedicated, integrated circuits, or to be made up, at least in part, of discrete components. In a software design, the interfaces may be software modules that are present, for example, on a microcontroller in addition to other software modules. The processing unit may be, for example, a signal processor, a microcontroller, or the like, and the memory unit may be a flash memory, an EEPROM, or a magnetic memory unit. The communication interface may be designed to read in or output data wirelessly and/or in a hard-wired manner. Also advantageous is a computer program product including program code that is stored on a machine-readable medium such as a semiconductor memory, a hard disk, or an optical memory, and used for carrying out the evaluation when the program is executed by the evaluation and control unit.

Advantageous enhancements of the method according to the present invention, for supplying energy to at least one electrical vehicle module, and of the voltage converter assembly according to the present invention, for supplying energy to at least one electrical vehicle module, are possible as a result of the measures and refinements disclosed here.

It is particularly advantageous that the load on the supply source may be switched off before the input voltage is converted into the at least one output voltage. The supply source may thus be prevented from being subjected to additional load during the voltage conversion.

In one advantageous example embodiment of the method of the present invention, the input voltage cannot be converted into the at least one output voltage if the input voltage drops below the predefinable setpoint voltage value due to the load on the supply source. A reliable voltage change or voltage conversion may thus be achieved due to the fact that the sporadic switching on and off is prevented.

In a further advantageous example embodiment of the method of the present invention, the supply source may be loaded, for example, with the predefinable current level for a predefinable time period. If the input voltage does not collapse during this time period, the supply source is sufficiently stable. The time period may advantageously be adapted to the specifications of the utilized supply sources and voltage converters.

In a further advantageous example embodiment of the method of the present invention, the load on the supply source may be switched off when the input voltage drops below the predefinable setpoint voltage value. Further damage to the supply source may thus be prevented or at least reduced.

In one advantageous example embodiment of the voltage converter assembly of the present invention, the evaluation and control unit may be designed to activate the at least one voltage converter as a function of predefinable criteria. The voltage monitor may be further designed to continuously compare the detected input voltage to a predefinable setpoint voltage value, and to output the comparison result to the evaluation and control unit. The comparison to a predefined setpoint voltage value allows very easily implementable monitoring of the input voltage. The evaluation and control unit may be further designed to activate a switchable current sink that loads the at least one supply source with a predefinable current level when the input voltage is above the predefinable threshold value. The use of a switchable current sink allows the load capacity of the supply source to be easily and quickly checked. In addition, the evaluation and control unit may activate the at least one voltage converter when the detected input voltage remains above the predefinable threshold value after the current sink is activated, or does not activate the at least one voltage converter if the input voltage drops below the predefinable setpoint voltage value due to the load on the supply source. A reliable voltage change or voltage conversion may thus be achieved, since the sporadic switching on and off may be reliably prevented.

In a further advantageous example embodiment of the voltage converter assembly of the present invention, the setpoint voltage value of the voltage monitor may be predefined as a fixed or freely selectable threshold value. A freely selectable threshold value allows better adaptation to the specifications of the utilized supply sources and voltage converters, while a fixed, predefined threshold value may be implemented more easily and cost-effectively.

In a further advantageous example embodiment of the voltage converter assembly of the present invention, the current level of the switchable current sink may be predefined as a fixed or freely selectable current value. A freely selectable current level allows better adaptation to the specifications of the utilized supply sources and voltage converters, while a fixed, predefined current level may be implemented more easily and cost-effectively.

In a further advantageous example embodiment of the voltage converter assembly of the present invention, the evaluation and control unit and the voltage monitor and the switchable current sink may be combined to form a monitoring device. The monitoring device may preferably be embodied as an application-specific integrated circuit (ASIC).

Exemplary embodiments of the present invention are illustrated in the figures and explained in greater detail in the following description. Components or elements that carry out identical or analogous functions are denoted by the same reference numerals in the figures.

### BRIEF DESCRIPTION OF THE DRAWINGS

FIG. 1 shows a schematic block diagram of one exemplary embodiment of a voltage converter assembly according to the present invention for supplying energy to at least one electrical vehicle module.

FIG. 2 shows a schematic flow chart of one exemplary embodiment of a method according to the present invention for supplying energy to at least one electrical vehicle module

### DETAILED DESCRIPTION OF EXAMPLE EMBODIMENTS

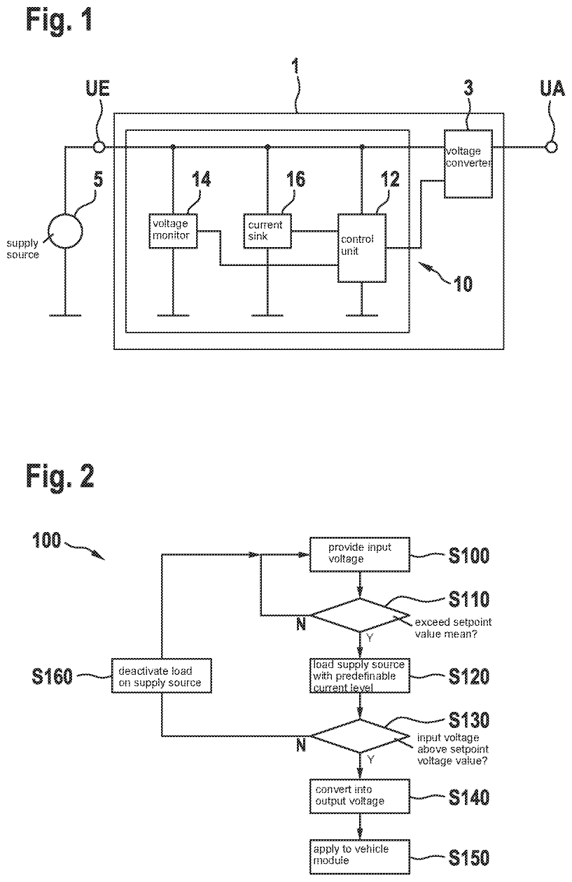

The illustrated exemplary embodiment of method 100 according to the present invention for supplying energy to at least one electrical vehicle module is described with reference to FIGS. 1 and 2. As is shown in FIG. 2, the illustrated exemplary embodiment of a method 100 according to the present invention for supplying energy to at least one electrical vehicle module includes a step S100 in which an input voltage UE that is provided by at least one supply source 5 is monitored. It is checked in a step S110 whether the applied input voltage UE exceeds a predefinable setpoint voltage value. If this is not the case, method 100 is continued with step S100. If input voltage UE exceeds the setpoint voltage value, supply source 5 is loaded with a predefinable current level in a step S120. It is checked in a step 130 whether input voltage UE remains above the predefinable setpoint voltage value despite the load on supply source 5. If this is not the case, method 100 is continued with a step S160 in which the load on supply source 5 is deactivated. The method is subsequently continued with step

S100. This means that input voltage UE is not converted into the at least one output voltage UA when input voltage UE drops below the predefinable setpoint voltage value due to the load on supply source 5. If input voltage UE remains above the setpoint voltage value despite the load on supply source 5, in a step

S150 input voltage UE is converted into at least one output voltage UA, which is applied to the at least one vehicle module.

In addition, in the illustrated exemplary embodiment the load on supply source 5 is switched off in a step, not illustrated, before input voltage UE is converted into the at least one output voltage UA in step S150. In the illustrated exemplary embodiment, supply source 5 is loaded with the predefinable current level for a predefinable time period.

As is further shown in FIG. 1, the illustrated exemplary embodiment of voltage converter assembly 1 according to the present invention for supplying energy to at least one electrical vehicle module includes at least one voltage converter 3 that is designed to convert input voltage UE, provided by the at least one supply source 5, into the at least one predefinable output voltage UA, which is applied to the at least one vehicle module (not illustrated), a voltage monitor 14 that is designed to detect input voltage UE, and an evaluation and control unit 12 that is designed to carry out method 100 according to the present invention for supplying energy to at least one electrical vehicle module.

In the illustrated exemplary embodiment of voltage converter assembly 1, evaluation and control unit 12 activates the at least one voltage converter 3 as a function of predefinable criteria, voltage monitor 14 continuously comparing detected input voltage UE to the predefinable setpoint voltage value, and outputting the comparison result to evaluation and control unit 12. Evaluation and control unit 12 activates a switchable current sink 16 that loads the at least one supply source 5 with the predefinable current level when input voltage UE is above the predefinable threshold value. Evaluation and control unit 12 activates the at least one voltage converter 3 when detected input voltage UE remains above the predefinable threshold value after current sink 16 is activated, or does not activate the at least one voltage converter when input voltage UE drops below the predefinable setpoint voltage value due to the load on supply source 5.

In the illustrated exemplary embodiment of voltage converter assembly 1, the setpoint voltage value of voltage monitor 14 is predefined as a fixed threshold value. In one exemplary embodiment of voltage converter assembly 1 that is not illustrated, the setpoint voltage value is a freely selectable threshold value and may be predefined as a function of the specifications of the utilized supply source 5 and the at least one voltage converter 3.

In the illustrated exemplary embodiment of voltage converter assembly 1, the current level of switchable current sink 16 is also predefined as a fixed current value. In one exemplary embodiment of voltage converter assembly 1 that is not illustrated, the current level is a freely selectable current value and may be predefined as a function of the specifications of the utilized supply source 5 and the at least one voltage converter 3.

As is further shown in FIG. 1, evaluation and control unit 12 and voltage monitor 14 and switchable current sink 16 are combined to form a monitoring device 10. This monitoring device 10 is preferably embodied as an application-specific integrated circuit (ASIC).

Method 100 according to the present invention for supplying energy to at least one electrical vehicle module may be implemented, for example, in software or hardware or in a mixed form made up of software and hardware, for example in evaluation and control unit 12.

1-10. (canceled)

11. A method for supplying energy to at least one electrical vehicle module, the method comprising:
monitoring an input voltage that is provided by at least one supply source; and
converting the input voltage into at least one output voltage which is applied to the at least one vehicle module;
wherein the supply source is loaded with a predefinable current level when the applied input voltage exceeds a predefinable setpoint voltage value, the input voltage being converted into the at least one output voltage when the input voltage remains above the predefinable setpoint voltage value despite the load on the supply source.

12. The method as recited in claim 11, wherein the load on the supply source is switched off before the input voltage is converted into the at least one output voltage.

13. The method as recited in claim 11, wherein the input voltage is not converted into the at least one output voltage when the input voltage drops below the predefinable setpoint voltage value due to the load on the supply source.

14. The method as recited in claim 11, wherein the supply source is loaded with the predefinable current level for a predefinable time period.

15. The method as recited in claim 11, wherein the load on the supply source is switched off when the input voltage drops below the predefinable setpoint voltage value.

16. A voltage converter assembly for supplying energy to at least one electrical vehicle module, comprising:
at least one voltage converter configured to convert an input voltage, provided by at least one supply source, into at least one predefinable output voltage, which is applied to the at least one vehicle module;
a voltage monitor configured to detect the input voltage; and
an evaluation and control unit configured to:
monitor the input voltage that is provided by the at least one supply source, and
convert, using the at least one voltage converter, the input voltage into the at least one predefinable output voltage which is applied to the at least one vehicle module;
wherein the supply source is loaded with a predefinable current level if the applied input voltage exceeds a predefinable setpoint voltage value, the input voltage being converted into the at least one predefinable output voltage if the input voltage remains above the predefinable setpoint voltage value despite the load on the supply source.

17. The voltage converter assembly as recited in claim 16, wherein the evaluation and control unit is configured to activate the at least one voltage converter as a function of predefinable criteria, the voltage monitor being further configured to continuously compare the detected input voltage to a predefinable setpoint voltage value, and to output a comparison result to the evaluation and control unit, the evaluation and control unit being further configured to activate a switchable current sink that loads the at least one supply source with the predefinable current level if the input voltage is above the predefinable threshold value, the evaluation and control unit configured to activate the at least one voltage converter if the detected input voltage remains above the predefinable threshold value after the current sink is activated, or to not activate the at least one voltage converter if the input voltage drops below the predefinable setpoint voltage value due to the load on the supply source.

18. The voltage converter assembly as recited in claim 17, wherein the setpoint voltage value of the voltage monitor is predefinable as a fixed or freely selectable threshold value.

19. The voltage converter assembly as recited in claim 17, wherein the current level of the switchable current sink is predefinable as a fixed or freely selectable current value.

20. The voltage converter assembly as recited in claim 17, wherein the evaluation and control unit and the voltage monitor and the switchable current sink together form a monitoring device.
